(19) United States
(12) Patent Application Publication
(10) Pub. No.: US 2008/0009104 A1
(43) Pub. Date: Jan. 10, 2008

(54) SEMICONDUCTOR PACKAGE HAVING ELECTROMAGNETIC INTERFERENCE SHIELDING AND FABRICATING METHOD THEREOF

(76) Inventor: Jau-Shoung Chen, Hsinchu County (TW)

Correspondence Address: NORTH AMERICA INTELLECTUAL PROPERTY CORPORATION, P.O. BOX 506, MERRIFIELD, VA, 22116, US

(21) Appl. No.: 11/562,968

(22) Filed: Nov. 22, 2006

(30) Foreign Application Priority Data
Jul. 4, 2006 (TW) 095124349

(51) Int. Cl. H01L 21/00

(52) U.S. Cl. 438/127

(57) ABSTRACT

A method of fabricating a semiconductor package having electromagnetic interference shielding starts with providing a substrate and a semiconductor device. Subsequently, a molding compound is provided. The molding compound covers the semiconductor device, and contacts with parts of the substrate. Next, a conductive adhesive layer is formed on the surface of the molding compound, and directly covers the top surface and the side surface of the molding compound. Because the conductive adhesive layer is utilized as an electromagnetic interference shielding, the fabricating process of the electromagnetic interference shielding is extremely simplified.

### BACKGROUND OF THE INVENTION

1. Field of the Invention

The present invention relates to a semiconductor package and a fabricating method thereof, and more specifically, to a method of fabricating a semiconductor package that forms a conductive adhesive layer on a surface of a molding compound.

2. Description of the Prior Art

In recent years, as information appliances and the electronics industry have developed, demand for superior functions and small volume have also increased accordingly. At the same time, due to the popularity of electronic products, the development of integrated circuits (IC) is moving toward high calculation speed, high component density, and multi-functional integration. Due to the improvement of calculation speed and the higher density of components, the occurrence of electromagnetic interference (EMI) becomes more likely between the IC and external electronic components.

Please refer to FIG. 1. FIG. 1 is a schematic diagram illustrating a prior art semiconductor package 10. As shown in FIG. 1, a semiconductor package 10 includes a substrate 30, a chip 31, a plurality of conductive wires 32, and a molding compound 33. The lower surface of the chip 31 can be adhered to the upper surface of the substrate 30 by chip glue so as to fix the chip 31 to the substrate 30. The conductive wires 32 electrically connect the bonding pads of the chip 31 to contact pads of the substrate 30. The molding compound 33 seals the chip 31 and the conductive wires 32 by a molding process so that the chip 31 and the conductive wires 32 can be protected from external force. Accordingly, many metal particles 331 must be included in the molding compound 33 so that the metal particles 331 can form an EMI shield to protect the chip 31 from EMI. Furthermore, in order to prevent a short circuit between the conductive wires 32 and the metal particles 331, every conductive wire 32 in the prior art should have a central conductive line 321 and a dielectric layer 322. The central conductive lines 321 are utilized to form the electrical connection. Meanwhile, the dielectric layers 322 should cover the surfaces of the central conductive lines 321 so as to prevent electrical contact between the central conductive lines 321 and the metal particles 331.

In the prior art semiconductor package 10, the dielectric layers 322 must surround the whole surface of the central conductive lines 321 to act as an insulator between the central conductive lines 321 and the molding compound 33. However, it complicates the manufacturing process of the semiconductor package 10, and decreases the throughput of the semiconductor package 10.

Please refer to FIG. 2. FIG. 2 is a schematic diagram illustrating a traditional semiconductor package 20. As shown in FIG. 2, a semiconductor package 20 includes a substrate 30, a chip 31, a molding compound 33, a metal case 34, and a plurality of conductive wires 36. The chip 31 is fixed to the substrate 30 by chip glue, and electrically connected to the substrate 30 by the conductive wires 36. The molding compound 33 seals the chip 31 and the conductive wires 36 so as to protect the chip 31 and the conductive wires 36. It should be noted that the metal case 34, which should be previously formed in a predetermined shape, must be included in the semiconductor package 20, and the chip 31, the conductive wires 36, and the molding compound 33 should be set in the space surrounded by the metal case 34 and the substrate 30, so the metal case 34 forms an EMI shield to protect the chip 31 from EMI.

In the traditional semiconductor package 20, the metal case 34 must be formed previously by other equipment, after which the traditional semiconductor package 20 is assembled. As a result, the fabrication time is greatly increased. Additionally, because packages of different sizes require the metal cases 34 in corresponding sizes, the cost of fabrication is also increased.

### SUMMARY OF THE INVENTION

It is the primary object of the present invention to provide a semiconductor package and fabricating method thereof to overcome the aforementioned problems.

According to the present invention, a method of fabricating a semiconductor package having electromagnetic interference shielding is disclosed. First, a substrate is provided, and the substrate comprises a ground terminal. Subsequently, a semiconductor device is provided on the substrate. Thereafter, a molding compound comprising a top surface and a side surface is provided. The molding compound covers the semiconductor device, and contacts with parts of the substrate. Next, a conductive adhesive layer is formed on the surface of the molding compound. The conductive adhesive layer directly covers the top surface and the side surface of the molding compound, and electrically connects to the ground terminal so as to provide electromagnetic interference shielding of the semiconductor package.

From one aspect of the present invention, a semiconductor package having electromagnetic interference shielding is disclosed. The semiconductor package comprises a substrate, at least a semiconductor device on the substrate, a molding compound comprising a top surface and a side surface, and a conductive adhesive layer. The substrate comprises a ground terminal. The molding compound covers the semiconductor device, and contacts parts of the substrate. The conductive adhesive layer directly covers the top surface and the side surface of the molding compound, and electrically connects to the ground terminal.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic diagram illustrating a prior art semiconductor package.

FIG. 2 is a schematic diagram illustrating a traditional semiconductor package.

FIG. 3 through FIG. 6 are schematic diagrams illustrating a method of fabricating a semiconductor package having electromagnetic interference shielding in accordance with a first preferred embodiment of the present invention.

FIG. 7 and FIG. 8 are schematic diagrams illustrating a method of fabricating a semiconductor package having electromagnetic interference shielding in accordance with a second preferred embodiment of the present invention.

FIG. 9 is a schematic diagram illustrating a semiconductor package having electromagnetic interference shielding in accordance with a third preferred embodiment of the present invention.

FIG. 10 is a schematic diagram illustrating a semiconductor package having electromagnetic interference shielding in accordance with a fourth preferred embodiment of the present invention.

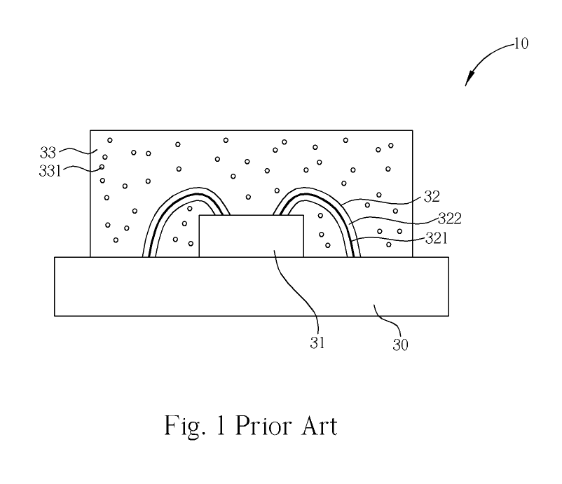

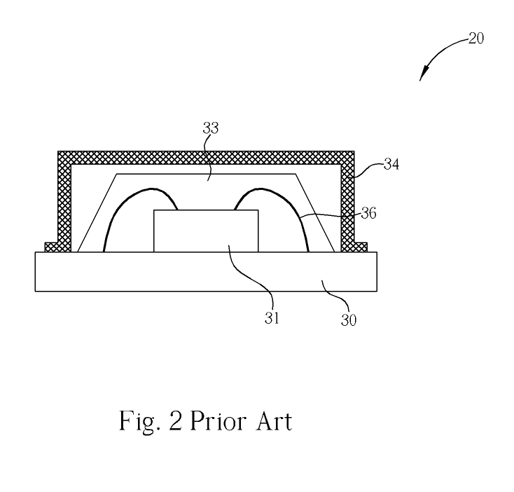

### DETAILED DESCRIPTION

In the following detailed description, reference is made to the accompanying drawings, which form a part of this application. The drawings show, by way of illustration, specific embodiments in which the invention may be practiced. It is to be understood that other embodiments may be utilized and structural changes may be made without departing from the scope of the present invention.

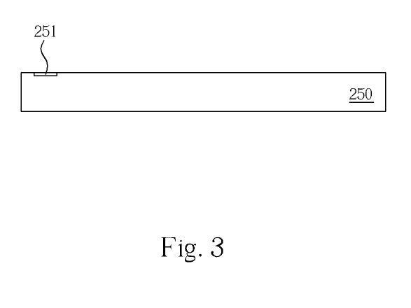

Please refer to FIGS. 3-6. FIGS. 3-6 are schematic diagrams illustrating a method of fabricating a semiconductor package 200 having electromagnetic interference shielding in accordance with a first preferred embodiment of the present invention. As shown in FIG. 3, a substrate 250 is first provided, such as a resin substrate, a glass substrate, a semiconductor substrate, a metal substrate, a single-layer circuit board, or a multiple-layer circuit board, and the substrate 250 comprises a ground terminal 251 on its surface. The ground terminal 251 can be electrically connected to a constant-voltage point, such as a ground point, through a metal interconnect circuit (not shown in the figure) of the substrate 250.

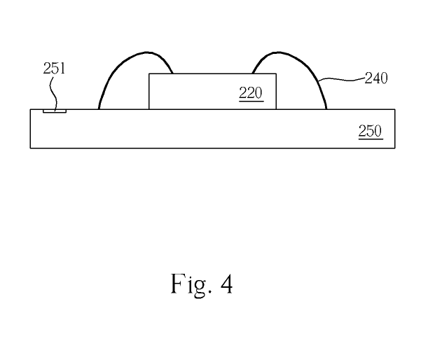

Subsequently, as shown in FIG. 4, at least a semiconductor device 220 is provided on the substrate 250. The semiconductor device 220 can be an active component, a passive component, or a chip, such as a one-time programmable device, a read only memory (ROM), or an analog circuit, depending on requirements. Thereafter, the semiconductor device 220 is fixed onto the surface of the substrate 250 by an adhesive. A wire bonding process or a flip chip bonding process is further performed so that a plurality of bonding pads (not shown in the figure) on the surface of the semiconductor device 220 can be electrically connected to the corresponding bonding pads on the surface of the substrate 250 through a plurality of conductive wires 240 or a plurality of solder bumps (not shown in the figure).

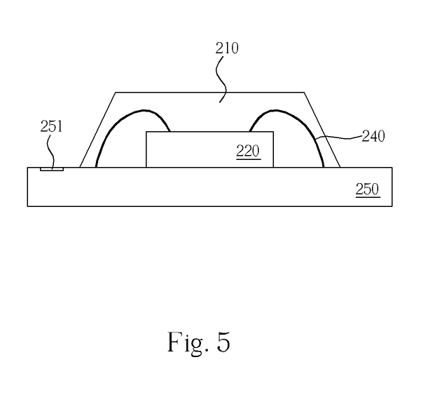

Thereafter, as shown in FIG. 5, a molding compound 210 is formed with thermosetting nonconductive materials, such as epoxy, silicone, or polyamide. The molding compound 210 covers the semiconductor device 220 and the substrate 250, and is solidified. Thus, the molding compound 210 can protect the semiconductor device 220 and the conductive wires 240 from being damaged or corroded by outside forces, moisture, and other materials.

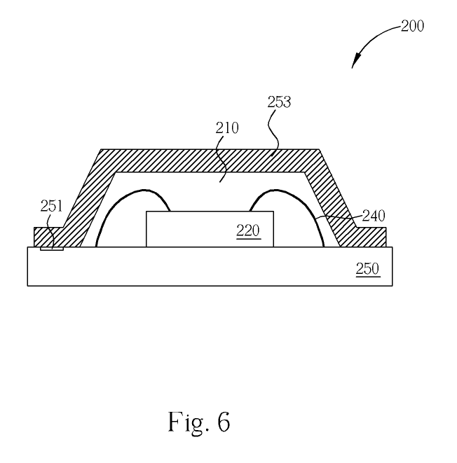

Next, as shown in FIG. 6, a conductive adhesive layer 253 is formed by coating, spraying, or printing, on the surface of the molding compound 210. The conductive adhesive layer 253 directly covers the top surface of the molding compound 210, the side surface of the molding compound 210, and the surface of the substrate 250 around the molding compound 210. Furthermore, the conductive adhesive layer 253 can directly cover the ground terminal 251 to form a shielding grounded circuit of an electromagnetic interference shield of the semiconductor package 200, and effectively decrease the electromagnetic interference. The conductive adhesive layer 253 comprises metal conductive particles and adhesive material, such as epoxy resin, polyurethane, or phenol formaldehyde. In addition, the conductive adhesive layer 253 can be an anisotropic conductive film (ACF) or an isotropic conductive film.

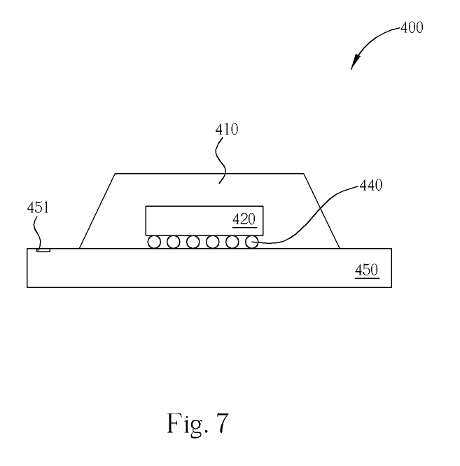

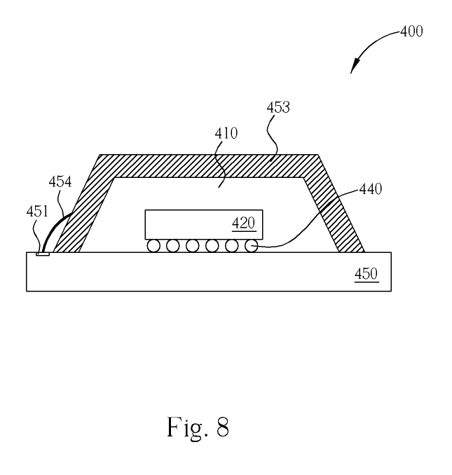

It is not necessary for the conductive adhesive layer to cover the ground terminal. Please refer to FIGS. 7 and 8. FIGS. 7 and 8 are schematic diagrams illustrating a method of fabricating a semiconductor package 400 having electromagnetic interference shielding in accordance with a second preferred embodiment of the present invention. As shown in FIG. 7, a substrate 450 having a ground terminal 451, a semiconductor device 420 on the substrate 450, and a molding compound 410, which covers the semiconductor device 420 and the substrate 450, are first provided. In this embodiment, the ground terminal 451 can be set on a surface of the substrate 450 that is not covered by the molding compound 410, and electrically connected to a ground point with a zero-voltage. Meanwhile, the semiconductor device 420 is electrically connected to the substrate 450 through a plurality of solder bumps 440.

Subsequently, as shown in FIG. 8, a conductive adhesive layer 453 is formed by coating, spraying, or printing, on the surface of the molding compound 410. The conductive adhesive layer 453 directly covers the top surface of the molding compound 410, the side surface of the molding compound 410, and the surface of the substrate 450 around the molding compound 410. It should be noted that the conductive adhesive layer 453 does not cover the ground terminal 451 in this embodiment, but is electrically connected to the ground terminal 451 through a bonding wire 454. As a result, electromagnetic interference shielding of the semiconductor package 400 is formed, and the electromagnetic interference is effectively decreased. The conductive adhesive layer 453 comprises metal conductive particles and adhesive material, such as epoxy resin, polyurethane, or phenol formaldehyde, and can be an anisotropic conductive film or an isotropic conductive film.

Because the conductive adhesive layer 253 and the conductive adhesive layer 453 are formed by coating, spraying, or printing, on the surfaces of the molding compound 210 and the molding compound 410 to provide electromagnetic interference shielding of the semiconductor package 200 and the semiconductor package 400, the manufacturing processes for forming the electromagnetic interference shielding are greatly simplified. Thus, the production cost of the semiconductor package 200 or the semiconductor package 400 is effectively decreased, and the whole yield of the semiconductor package is raised.

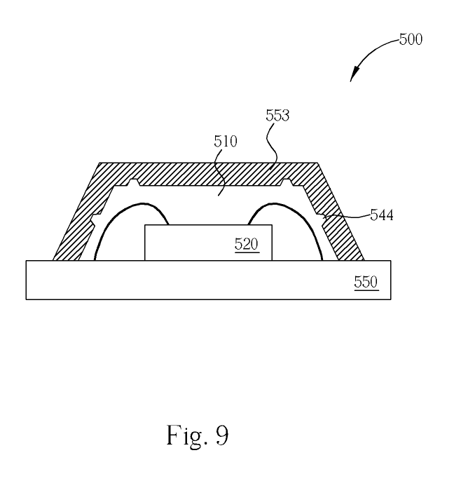

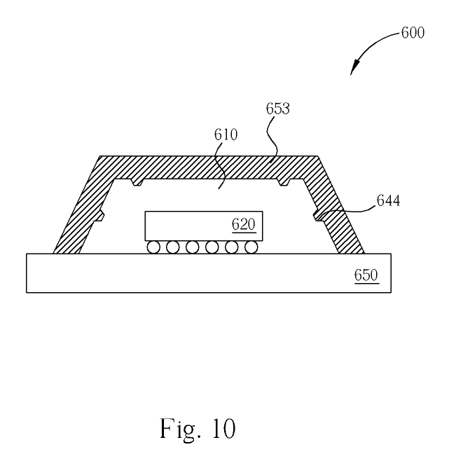

The spirit of the present invention should not be limited to the above-mentioned embodiments. Please refer to FIGS. 9 and 10. FIGS. 9 and 10 are schematic diagrams illustrating semiconductor packages 500, 600 having electromagnetic interference shielding in accordance with a third and a fourth preferred embodiment of the present invention, respectively. The semiconductor package 500 in the third preferred embodiment has a substrate 550, at least a semiconductor device 520 on the substrate 550, a molding compound 510, which covers the semiconductor device 520 and parts of the substrate 550, and a conductive adhesive layer 553, which directly covers the top surface of the molding compound 510, the side surface of the molding compound 510, and the surface of the substrate 550 around the molding compound 510. It is worthy of note that the surface of the molding compound 510 in this embodiment can be a rough surface or a surface having a micro-pattern. As shown in FIG. 9, the surface of the molding compound 510 has a plurality of protuberant structures 544, which may be formed by an etching process, a machining process, or a monolithic forming process. The contact area between the molding compound 510 and the conductive adhesive layer 553 is therefore increased, and the adhesive force of the conductive adhesive layer 553 on the molding compound 510 is increased due to the protuberant structures 544. As a result, the electromagnetic interference shielding in the semiconductor package is much firmer.

As shown in FIG. 10, the semiconductor package 600 in the fourth preferred embodiment has a substrate 650, at least a semiconductor device 620 on the substrate 650, a molding compound 610, which covers the semiconductor device 620 and parts of the substrate 650, and a conductive adhesive layer 653, which directly covers the top surface of the molding compound 610, the side surface of the molding compound 610, and the surface of the substrate 650 around the molding compound 610. It should be noted that the surface of the molding compound 610 has a plurality of cavity structures 644, which may be formed by an etching process, a mechanical working process, or a monolithic forming process. The contact area between the molding compound 610 and the conductive adhesive layer 653 is therefore increased, and the adhesive force of the conductive adhesive layer 653 on the molding compound 610 is promoted due to the cavity structures 644. As a result, the electromagnetic interference shielding in the semiconductor package is much firmer.

Because the respective conductive adhesive layers are formed by coating, spraying, or printing, on the surface of the molding compound to provide electromagnetic interference shielding of the semiconductor package, the manufacturing processes for forming the electromagnetic interference shielding are greatly simplified. Thus, the production cost of the semiconductor package is effectively decreased, and the whole yield of the semiconductor package is raised. Furthermore, because the respective conductive adhesive layers are easily deformed, the protuberant structures and the cavity structures formed on the respective contact surfaces can be easily formed while the molding compound and the conductive adhesive layer are made. Therefore, the adhesive force of the conductive adhesive layer on the molding compound is improved, and the electromagnetic interference shielding in the semiconductor package is much firmer.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method of fabricating a semiconductor package having electromagnetic interference shielding, comprising:
providing a substrate comprising a ground terminal;
providing a semiconductor device on the substrate;
providing a molding compound comprising a top surface and a side surface, the molding compound covering the semiconductor device, and contacting parts of the substrate; and
forming a conductive adhesive layer on the molding compound, the conductive adhesive layer directly covering the top surface and the side surface of the molding compound and electrically connected to the ground terminal.

2. The method of claim 1, wherein the conductive adhesive layer is formed by coating.

3. The method of claim 1, wherein the conductive adhesive layer is formed by spraying.

4. The method of claim 1, wherein the conductive adhesive layer is formed by printing.

5. The method of claim 1, wherein the conductive adhesive layer is an anisotropic conductive film (ACF).

6. The method of claim 1, wherein the conductive adhesive layer comprises conductive particles and adhesive material, such as epoxy resin, polyurethane, or phenol formaldehyde.

7. The method of claim 1, wherein the ground terminal is positioned on a surface of the substrate.

8. The method of claim 7, wherein the conductive adhesive layer covers the ground terminal.

9. The method of claim 7 further comprising a step of wire bonding for forming a bonding wire electrically connecting the conductive adhesive layer and the ground terminal.

10. A semiconductor package having electromagnetic interference shielding comprising:
a substrate comprising a ground terminal;
at least a semiconductor device on the substrate;
a molding compound comprising a top surface and a side surface, the molding compound covering the semiconductor device, and contacting parts of the substrate; and
a conductive adhesive layer directly covering the top surface and the side surface of the molding compound, and electrically connected to the ground terminal.

11. The semiconductor package of claim 10, wherein the conductive adhesive layer further covers a surface of the substrate around the molding compound.

12. The semiconductor package of claim 10, wherein the molding compound is a nonconductive molding compound.

13. The semiconductor package of claim 10, wherein the conductive adhesive layer is an anisotropic conductive film.

14. The semiconductor package of claim 10, wherein the conductive adhesive layer comprises conductive particles and adhesive material, such as epoxy resin, polyurethane, or phenol formaldehyde.

15. The semiconductor package of claim 10, wherein the semiconductor device is electrically connected to the substrate through a plurality of conductive wires.

16. The semiconductor package of claim 10, wherein the semiconductor device is electrically connected to the substrate through a plurality of solder bumps.

17. The semiconductor package of claim 10, wherein the semiconductor device is fixed on the substrate by a glue.

18. The semiconductor package of claim 10, wherein the ground terminal is positioned on a surface of the substrate.

19. The semiconductor package of claim 18, wherein the conductive adhesive layer covers the ground terminal.

20. The semiconductor package of claim 18, further comprising a bonding wire electrically connecting the conductive adhesive layer and the ground terminal.
